(19) United States
(12) Patent Application Publication
(10) Pub. No.: US 2024/0123791 A1
(43) Pub. Date: Apr. 18, 2024

(54) PRECONDITIONING SURFACES USING INTELLIGENT THERMAL EFFECTORS

(71) Applicant: GENTHERM INCORPORATED, Northville, MI (US)

(72) Inventors: Kenneth Turner, Novi, MI (US); Amey Pise, Farmington Hills, MI (US); Chad Vincent Pacilli, Windsor (CA)

(21) Appl. No.: 18/547,077

(22) PCT Filed: Mar. 16, 2022
(86) PCT No.: PCT/US2022/071182

§ 371 Date: Aug. 18, 2023

Related U.S. Application Data
(60) Provisional application No. 63/162,973, filed on Mar. 18, 2021.

(51) Int. Cl. B60H 1/00; B60N 2/00; B60N 2/56

(52) U.S. Cl. CPC B60H 1/00285; B60H 1/00478; B60H 1/00742; B60H 1/00828; B60H 1/00878; B60N 2/0034; B60N 2/0035; B60N 2/5657; B60N 2/5692; B60H 2001/003

(57) ABSTRACT

A thermal conditioning system for conditioning a seat surface of a vehicle or other surface. The system includes a thermoelectric Peltier device with a main side and a waste side. A flap adjusts a proportion of an airflow between a main side airflow path and a waste side airflow path based on whether the surface is occupied, the power provided the thermoelectric Peltier device, the flow rates along the airflow paths, the power provided to a blower, and/or other factors.

### CROSS REFERENCE

This application claims the benefit of U.S. Patent Application No. 63/162,973, filed Mar. 18, 2021, the entirety of which is hereby incorporated by reference.

### BACKGROUND

### Field

This disclosure generally relates to thermoelectric climate conditioning systems.

### Related Art

Climate control systems, such as heating systems and air conditioning systems, can be used to thermally condition extensive areas, such as entire buildings, suites, or individual rooms. The cabin space of a vehicle is also typically conditioned as a unit using conventional climate control systems. However, more selective environmental conditioning can also be desirable in many contexts such as, for example, the heating or cooling of a passenger seat in a vehicle. Accordingly, various types of individualized climate control systems for vehicle seats and other environments have been used.

### SUMMARY

According to one aspect, a control method for conditioning a surface with a thermal conditioning system having a thermoelectric device (TED), includes determining whether the surface is occupied, providing power to the TED, the TED including a main side and a waste side, providing an airflow with a blower, and adjusting a proportion of the airflow between a main side flow path across the main side of the TED and a waste side flow path across the waste side of the TED based on whether the surface is occupied.

According to another aspect, determining whether the surface is occupied is based on a signal received from a force sensor in a vehicle seat. According to another aspect, determining whether the surface is occupied is based on whether a vehicle is remotely started. According to another aspect, the control method is a startup mode. According to another aspect, determining whether the surface is occupied is based on comparing a delta-T between the temperature of the TED and a temperature of ambient cabin air with an expected delta-T between the temperature of the TED and the temperature of ambient cabin air based at least on a position of a flow control valve. According to another aspect, the thermal conditioning system is operated in a heater mode. According to another aspect, the thermal conditioning system is operated in a cooling mode. According to another aspect, the power provided to the TED is based on whether the surface is occupied. According to another aspect, the power provided to the TED is based on the surface being determined to be unoccupied. According to another aspect, the power provided to the TED is 100%. According to another aspect, adjusting the proportion of the airflow between the main side flow path and the waste side flow path includes adjusting a position of a flow control valve to a first position. According to another aspect, the first position of the flow control valve is based on the surface being determined to be unoccupied. According to another aspect, the first position of the flow control valve directs the airflow between the main side flow path and the waste side flow path at a ratio between 1:99 and 30:70. According to another aspect, adjusting the flow control valve to a second position is based on detecting a set temperature of the airflow. According to another aspect, the second position of the flow control valve directs more airflow along the main side flow path than in the first position. According to another aspect, the second position of the flow control valve directs the airflow between the main side flow path and the waste side flow path at a ratio between 30:70 and 95:5. According to another aspect, regulating the power provided to the TED is based on detecting the set temperature of the airflow. According to another aspect, the power provided to the TED is reduced based on detecting the set temperature. According to another aspect, adjusting the flow control valve to a third position is based on an in-cabin air temperature. According to another aspect, the third position closes the waste side flow path. According to another aspect, the in-cabin air temperature is based on a signal from an NTC. According to another aspect, the power provided to the TED is reduced based on the in-cabin air temperature. According to another aspect, the power provided to the TED is shut off. According to another aspect, increasing a speed of the blower increases a speed of the airflow. According to another aspect, the first position of the flow control valve is based on the surface being determined to be occupied. According to another aspect the first position of the flow control valve directs the airflow between the main side flow path and the waste side flow path at a ratio between 30:70 and 95:5. According to another aspect adjusting the flow control valve to a second position is based on determining that the surface has changed from unoccupied to occupied. According to another aspect the second position of the flow control valve directs more airflow along the main side flow path than in the first position. According to another aspect adjusting the flow control valve to a third position is based on an in-cabin air temperature.

According to a second aspect, a thermal conditioning system for conditioning a surface includes a thermoelectric device (TED) with a main side and a waste side. An airflow path extends along a main side flow path on the main side of the TED and along a waste side flow path along the waste side of the TED. A processor couples with a non-transitory computer readable medium containing a set of instructions, the instructions, when executed by the processor, configured to: determine whether the surface is occupied, provide power to the TED; provide an airflow along the airflow path with a blower; and adjust a proportion of the airflow between the main side flow path and the waste side flow path based on whether the surface is occupied.

According to another aspect, determining whether the surface is occupied is based on a signal received from a force sensor in a vehicle seat. According to another aspect, determining whether the surface is occupied is based on whether a vehicle is remotely started. According to another aspect, determining whether the surface is occupied is based on comparing a delta-T between the temperature of the TED and a temperature of ambient cabin air with an expected delta-T between the temperature of the TED and the temperature of ambient cabin air based at least on a position of a flow control valve. According to another aspect, the power provided to the TED is based on whether the surface is occupied. According to another aspect, adjusting the proportion of the airflow between the main side flow path and the waste side flow path includes adjusting a position of a flow control valve to a first position. According to another aspect, the first position of the flow control valve is based on the surface being determined to be unoccupied. According to another aspect, the first position of the flow control valve directs the airflow between the main side flow path and the waste side flow path at a ratio between 1:99 and 30:70. According to another aspect, adjusting the flow control valve to a second position is based on detecting a set temperature of the airflow. According to another aspect, the second position of the flow control valve directs more airflow along the main side flow path than in the first position. According to another aspect, the second position of the flow control valve directs the airflow between the main side flow path and the waste side flow path at a ratio between 30:70 and 95:5. According to another aspect, regulating the power provided to the TED is based on detecting the set temperature of the airflow. According to another aspect, the power provided to the TED is reduced based on detecting the set temperature. According to another aspect, the instructions, when executed by the processor, are further configured to adjust the flow control valve to a third position based on an in-cabin air temperature. According to another aspect, the third position closes the waste side flow path. According to another aspect, the in-cabin air temperature is based on a signal from an NTC. According to another aspect, the power provided to the TED is reduced based on the in-cabin air temperature. According to another aspect, the power provided to the TED is shut off. According to another aspect, the instructions, when executed by the processor, are further configured to increase a speed of the blower to increase a speed of the airflow. According to another aspect, the first position of the flow control valve is based on the surface being determined to be occupied. According to another aspect, the first position of the flow control valve directs the airflow between the main side flow path and the waste side flow path at a ratio between 30:70 and 95:5. According to another aspect, the instructions, when executed by the processor, are further configured to adjust the flow control valve to a second position based on determining that the surface has changed from unoccupied to occupied. According to another aspect, the second position of the flow control valve directs more airflow along the main side flow path than in the first position. According to another aspect, the instructions, when executed by the processor, are further configured to adjust the flow control valve to a third position based on an in-cabin air temperature.

The foregoing summary is illustrative only and is not intended to be limiting. Other aspects, features, and advantages of the systems, devices, and methods and/or other subject matter described in this application will become apparent in the teachings set forth below. The summary is provided to introduce a selection of some of the concepts of this disclosure. The summary is not intended to identify key or essential features of any subject matter described herein.

### BRIEF DESCRIPTION OF THE DRAWINGS

Various examples are depicted in the accompanying drawings for illustrative purposes, and should in no way be interpreted as limiting the scope of the examples. Various features of different disclosed examples can be combined to form additional examples, which are part of this disclosure.

FIG. 1 shows a thermal conditioning system including a blower for providing an airflow across main and waste sides of a thermoelectric device (TED) and a flow control valve for dividing the airflow between the main and waste sides;

FIG. 2A shows a cross sectional view of a seat including the thermal conditioning system in a low-flow/high delta-T configuration with the flow control valve primarily blocking airflow over the main side of the TED;

FIG. 2B shows the cross sectional view of the seat including the thermal conditioning system in a median or nominal-flow configuration with the flow control valve allowing airflow over the main side and waste side of the TED;

FIG. 2C shows a cross sectional view of a seat including the thermal conditioning system in a vent or high-flow configuration with the flow control valve blocking airflow over the waste side of the TED;

FIG. 3A shows a heat map of the seat surface with the thermal conditioning system in the low-flow/high delta-T configuration;

FIG. 3B shows a heat map of the seat surface with the thermal conditioning system in the nominal-flow configuration;

FIG. 4 shows an algorithm for operating the thermal conditioning system for preconditioning a touch surface based on whether the surface is occupied or unoccupied.

### DETAILED DESCRIPTION

The various features and advantages of the systems, devices, and methods of the technology described herein will become more fully apparent from the following description of the examples illustrated in the figures. These examples are intended to illustrate the principles of this disclosure, and this disclosure should not be limited to merely the illustrated examples. The features of the illustrated examples can be modified, combined, removed, and/or substituted as will be apparent to those of ordinary skill in the art upon consideration of the principles disclosed herein.

### Thermal Conditioning Systems

In various scenarios, it can be desirable to pre-heat or pre-cool a touch surface to a pre-set temperature before that surface is occupied using a thermal conditioning system. As one example, the touch surfaces in a vehicle seat may be uncomfortably hot or cold depending on the exterior or interior environment of the vehicle. The touch surfaces of a vehicle seat within a vehicle parked during wintertime in a non-climate controlled environment may require pre-heating to a comfortable temperature. Likewise, the touch surfaces of a vehicle seat within a vehicle parked in the sun during summer may require pre-cooling to a comfortable temperature.

Existing gross climate control technologies can precondition a touch surface through contact with the ambient air, such as the air-conditioning within a vehicle cabin. Nevertheless, a more targeted preconditioning system offers various advantages over existing systems. Thermal conditioning systems can have a faster effect on the touch surface and achieve such effects in a more efficient manner. Moreover, targeting specific touch surfaces for preconditioning can facilitate a more comfortable user experience without wasting energy on non-touch surfaces. In the context of an automobile, touch surfaces may commonly include seats, arm rests, head rests, and/or other surfaces within a vehicle cabin.

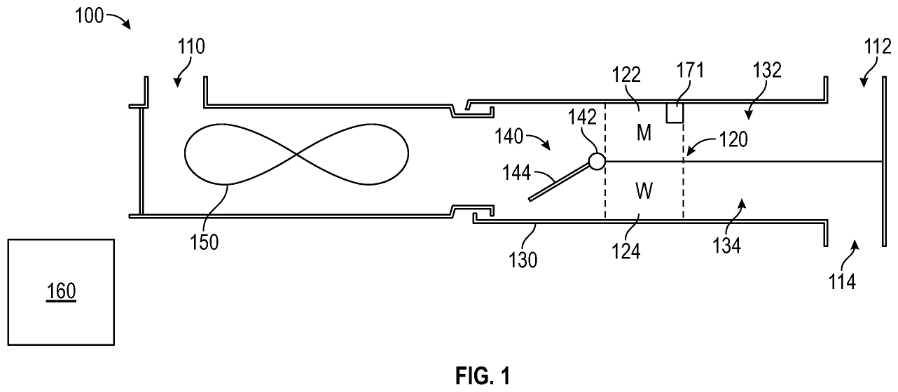

FIG. 1 shows an implementation of a thermal conditioning system 100 suitable for use to precondition a touch surface. The thermal conditioning system 100 can be used to deliver conditioned (e.g., heated, cooled, dried, and/or wetted) air to a climate-controlled device or environment. In an exemplary implementation, the thermal conditioning system 100 can deliver conditioned air into a vehicle seat, such as through one or more passages or channels within the vehicle seat. The thermal conditioning system 100 can also be used to provide conditioned air to various other spaces or components such as head rests, arm rests, an enclosed spaces, beds, furniture, or any touch surface that may benefit from thermal conditioning. Other implementations of thermal conditioning systems are described in WO 2020/112902, the entirety of which is hereby incorporated by reference.

The thermal conditioning system 100 can include a flow path therethrough. The flow path can extend through an outer housing 130 of the thermal conditioning system 100. The flow path can include an inlet 110 and one or more outlets 112, 114. Fluid, such as ambient air, can be drawn in through the inlet 110, conditioned using one or more conditioning elements within the system 100, and exhausted through the outlet(s) 112, 114, at least one of which provides conditioned air to the desired location.

The conditioning elements of the thermal conditioning system 100 can include a thermoelectric device (TED) 120. The TED 120 can be a Peltier device. The TED 120 can include a main-side 122 and a waste side 124. The flow path can include a main side flow path 132 that extends across the main side 122 of the TED 120 to the main outlet 112. The flow path can include a waste side flow path 134 that extends across the waste side 124 of the TED 120 to the waste outlet 114. The main-side flow path 132 can terminate at the climate-controlled environment or passageway thereto. The waste-side flow path 134 can terminate at an exhaust. The main and waste sides 122, 124 can each include a heat exchanger, such as one or more fins to enhance heat transfer between the TED 120 and the airflow passing along the respective main and/or waste side flow paths 132, 134.

The TED 120 can be connected with an voltage or amperage source such that the TED heats one side and cools the opposite side. Modification of the applied voltage or amperage can cause cooling of the main side 122 and heating of the waste side 124, or operated in the reverse polarity to cool the waste side 124 and heat the main side 122. When used as a cooling device, the main-side 122 can be colder than the waste side 124. When used as a heating device, the main-side 122 can be hotter than the waste side 124. The amount of power provided to the TED 120 can be adjusted using a duty cycle through pulse-width modulation (PWM). The TED 120 may include a temperature sensor 171, such as an NTC. The heat sensor may be located on the main side 122, such as on one of the fins.

The thermal conditioning system 100 can include or be used in combination with a blower 150, or other fluid moving device. The blower 150 can include a motor for driving one or more blades. A speed of the blower 150 can controlled based on application of a voltage and/or amperage to the motor. The blower 150 can deliver the airflow (e.g., ambient air or another fluid) along the flow path through the thermal conditioning system 100. The blower 150 can draw air in from the inlet 110 and move the air along the flow path past the TED 120 to outlets 112, 114. In the illustrated system 100, the blower 150 can be positioned, in general, upstream of the conditioning elements of the thermal conditioning system 100. However, in other implementations, a blower 150 can be positioned downstream of the conditioning elements in addition to or in the alternative to an upstream blower.

The thermal conditioning system 100 can include a flow control valve 140. The flow control valve 140 can portion the airflow provided by the blower 150 between the main and waste-side flow paths 132, 134. The flow control valve 140 can be upstream of the TED 120. The flow control valve 140 can include a louver or flap 144. The flap 144 can be connected with a movable pivot 142. A position of the flap 144 and pivot 142 can be controlled by a motor (e.g., a servo, step, or other motor type) or other actuator. The flap 144 can be pivotable about the pivot 142 through an angle A. The angle A can vary to fully or partially close each of the main side flow path 132 and the waste side flow path 134. The effect of the position of the flap 144 on the temperature of the conditioned air at the outlet 112 is further described in WO 2020/112902.

In the illustrated implementation, the flow control valve 140 is in the form of a flap valve, however other types of valves could be used such as needle, barrel or rotary valves and/or a combination of such valves. Moreover, it is anticipated that in other implementations the flow control valve 140 can be positioned downstream of the TED 120 and/or that additional valves can be provided. For example, individual valves could be provided each of the main and waste side flow paths 132, 134.

The system 100 can further include or be connected with a controller 160. The controller 160 may include a singular unit or distributed across several devices. The controller 160 can include a processor and a non-transitory computer readable medium configured to store instructions that are executable by the processor to operate the system 100 according to one or more control instructions and methods, as discussed further below. Operation of the system 100 by the controller 160 can be based adjusting operation of one or more of the components thereof. A primary control mechanism of the system 100 can be to adjust the power supplied to the TED 120 (e.g. by controlling the duty cycle that regulates the electrical power supplied to the TED). The power provided to the TED 120 may have the largest impact on total electrical power consumption of the system 100. A secondary control mechanism of the system 100 is adjusting the position of the flow control valve 140. The position of the flow control valve 140 controls the portion of the total air flow that passes the main side of the TED 120 and can adjust the temperature and amount of the airflow passing to the outlet 112 and/or outlet 114. A tertiary control mechanism of the system 100 is to regulate the speed of the blower 150. The blower 150 can control the total air flow rate through the system 100 and accordingly the temperature and amount of the airflow passing therethrough to the outlet 112.

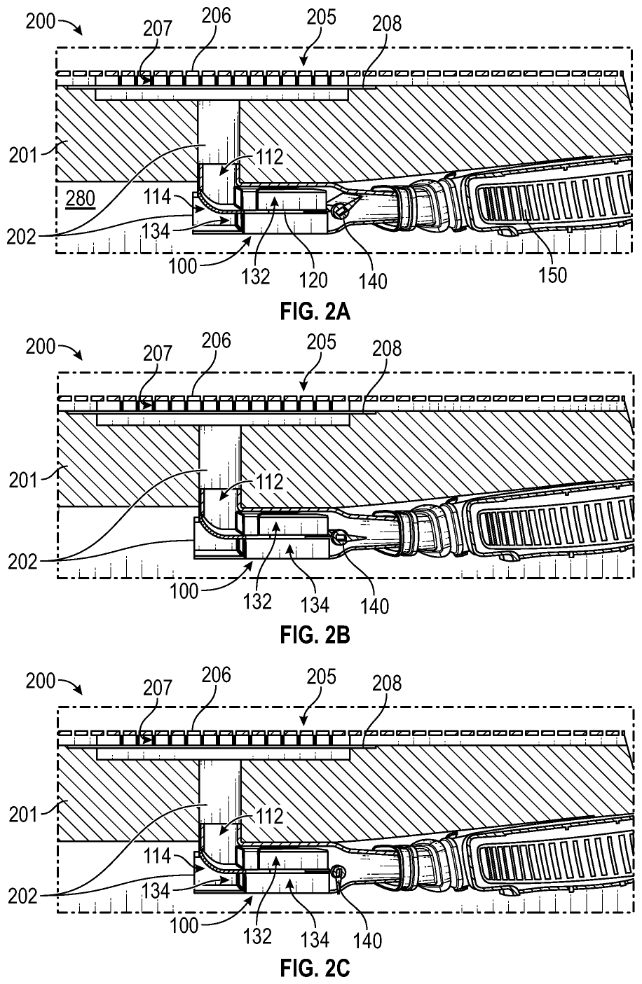

FIGS. 2A-C show a seat 200 for use with the thermal conditioning system 100, in one exemplary implementation. The seat 200 can include a cushion 201 covered by one or more internal and/or external layers forming a touch surface 205 of the seat 200. The touch surface can include an upper surface 206. The upper surface 206 can be formed of a flexible material such as natural or synthetic fabrics or leather. The upper surface 206 can be air permeable, perforated or otherwise ventilated to allow the passage of airflow therethrough from the system 100. Internal layers 207 of the touch surface 205 can further include a heater pad 208, spacers, comfort layers, etc. These internal layers may also be ventilated.

The cushion can include one or more passageways 202 in communication with the touch surface 205. The passageways 202 can connect the system 100 with the touch surface 205 by providing a flow path through the seat 200. Specifically, the outlet 112 and/or the waste outlet 114 of the system 100 can connect with the passageways 202 to allow the airflow therethrough. The passageways 202 can enable the flow of air with more or less resistance from the outlet 112 to the touch surface 205. The system 100, or one or more components thereof, can be embedded within the cushion 201 within such the passageways 202. In one implementation, the TED 120, flow control valve 140, and/or blower 150 are contained within the seat 200. Another passageway (not shown) can connect the inlet 110 with ambient air (e.g., contained within the cabin of a vehicle).

### Preconditioning Touch Surfaces

The thermal conditioning system 100 can be used to precondition a touch surface, such as the touch surface 205, to a pre-selected temperature. The higher the difference between the pre-selected temperature of the touch surface 205 and the ambient air (delta-T) or surrounding touch surfaces, the more pronounced is the sensation felt by the occupant. The delta-T producible by a thermal conditioning system can be related to the volume of conditioned airflow from such the system. Accordingly, one aspect of the present disclosure includes strategies for preconditioning a touch surface more effectively by modifying the volume of an conditioned airflow.

Another factor that affects the delta-T of a touch surface using a thermal conditioning system is whether the touch surface is occupied or unoccupied. Temperatures of unoccupied touch surfaces can change (either rising or cooling depending on system mode) more slowly than for an occupied surface. Also, energy in the form of heated or cooled air that gets to the surface can quickly be lost to the environment rather than being insulated or absorbed by a seat occupant. This may result in wasted energy, as well as a lower delta-T for the touch surface. Conversely, an occupied touch surface generally inhibits the passage of a conditioned airflow therethrough. Accordingly, generally higher airflow volumes may be used.

Previous active cooling systems do not have ability to vary airflow and temperature to be able to drive to more extreme set point temperatures (higher delta-T) producible by the system 100 in a cooling mode. These systems also do not have the ability to reduce airflow and maintain temperature target simultaneously. Previous active heating systems generally include a thermal barrier between a heater mat and an exterior surface (e.g., seat surface). This thermal barrier slows the transfer of heat to the surface produced at the heater mat. By utilizing the system 100 in heating mode heated air can be forced up to the surface to supplement the heater mat when the seat is unoccupied (e.g., remote/cold start conditions or occupied (e.g., cold start conditions).

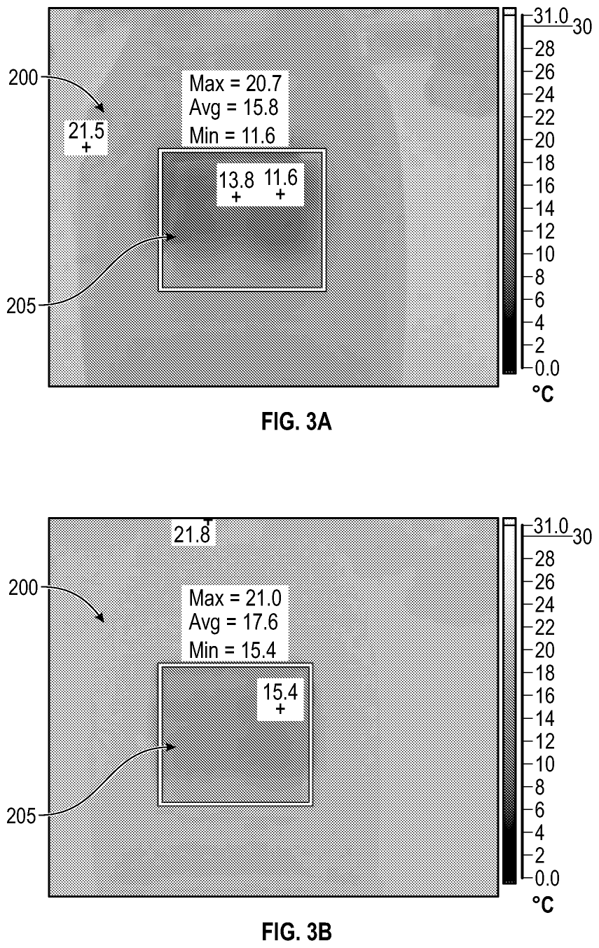

FIGS. 3A-B shows a heat map corresponding to the touch surface 205 of the seat 200 as shown in corresponding FIGS. 2A-B with the system 100 in a cooling mode. In both FIGS. 3A and 3B, the touch surface 205 is unoccupied and exhibits a delta-T relative to adjacent seat surfaces. To achieve the lower touch surface temperature in FIG. 3A (13.8° C.) compared with the delta-T in FIG. 3B (15.4° C.), the system 100 is used in the low-flow/high delta-T configuration, as shown in FIG. 2A. In the low-flow/high delta-T configuration, the flow control valve 140 is positioned to primarily block the airflow from the blower 150 along the main side flow path 132. The ratio of airflow between the main side flow path 132 and the waste side flow path 134 can vary depending on the system 100. In certain implementations of the low-flow/high delta-T configuration, the airflow between the main side flow path 132 and the waste side flow path 134 can be at a ratio of approximately 10:90 or 5:95, or between 1:99 and 30:70 or anywhere between 0:100 and 30:70.

The low-flow/high delta-T configuration is more effective at producing a high delta-T than the nominal-flow configuration for several reasons. First, reducing the airflow along the main side flow path 132 enables the TED 120 to more fully heat or cool the airflow. The temperature of the airflow can approach the temperature of the main side 122 of the TED 120. Second, a lower volume of airflow escapes to the environment through the touch surface 205. The energy contained within the conditioned airflow is more fully transferred into the touch surface 205 because of both the lower volume of air and the higher delta-T. This enables the touch surface 205 to adequately precondition without losing excessive energy into the environment. Third, more waste side airflow allows for more effective removal of waste heat, reducing the temperature of the entire system.

In contrast to the delta-T in FIG. 3A, the delta-T in FIG. 3B is effected by using the system 100 in a nominal-flow configuration, as shown in FIG. 2B. In the nominal-flow configuration, the flow control valve 140 is positioned to primarily allow the airflow from the blower 150 along the main side flow path 132. In certain implementations of the nominal-flow configuration, the airflow between the main side flow path 132 and the waste side flow path 134 can be at a ratio of 50:50, between 40:60 and 60:40, between 30:70 and 95:5, or between 30:70 and 99:1. Allowing high flow on both the main and waste sides of the TED 120 can allow the TED 120 to operate more efficiently than high flow on only a single side.

The nominal-flow configuration for the system 100 can be more effective when the seat 200 is occupied. The occupied seat 200 can block passage of the airflow through the touch surface 205. Accordingly, higher volumes of conditioned airflow (e.g., relative to the low airflow/high delta-T configuration) may be necessary to produce cooling or heating of the touch surface 205. Higher airflow moving across an occupant can result in more evaporative and convective cooling. Moreover, the use of a higher volume of conditioned air may be used to convectively cool the seat occupant. After the set temperature is reached, power to the TED 120 may be reduced to maintain the set temperature (e.g., via duty cycle modification) of the conditioned airflow.

FIG. 2C shows the system 100 in a vent configuration with the flow control valve 140 either entirely or mostly blocking airflow across the waste side 124. The TED 120 may also be on a low-duty cycle or entirely shut off. Airflow through the system 100 can be entirely or mostly through the main side flow path 132. The vent configuration can be utilized where the conditions of the air entering the system 100 through the inlet 110 is sufficiently heated or cooled to provide the desirable sensation to the passenger at the seat surface 206. As one example, the cabin air in the vehicle has reached the desired set point temperature, either air conditioned or heated. At that point blowing the cabin air through the system 100 without further cooling can be acceptable for cooling the seat occupant. Generally, the vent configuration is not used for heating purposes. The vent configuration can be used as a drying mode for the components of the system 100 and/or the occupant. The vent configuration can also be used to maximize or otherwise increase evaporative cooling effects under certain environmental conditions

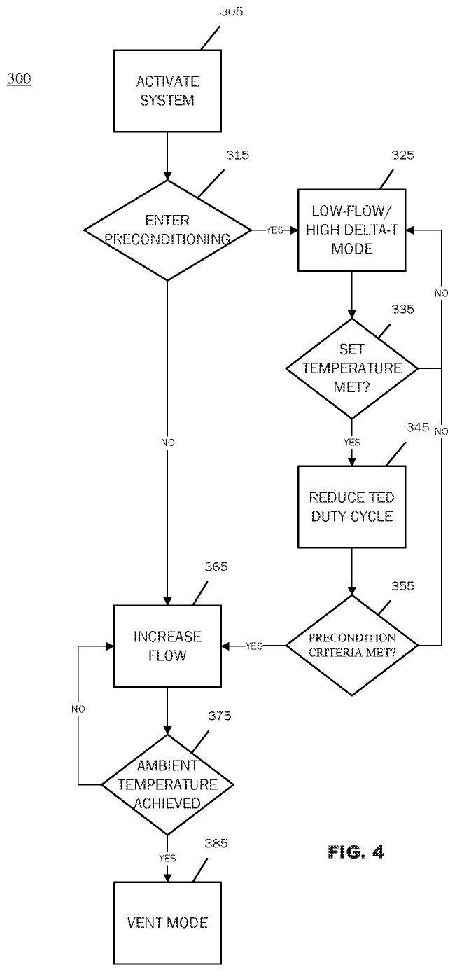

FIG. 4 shows a preconditioning method 300 for the exemplary touch surface 205 of the seat 200 using the system 100. At Step 305, the system 100 can be activated. The activation of the system 100 can be done remotely or locally (e.g., based on a user starting or remotely starting a vehicle containing the system 100).

At Step 315, the system 100 can determine whether to activate a heating or cooling mode to precondition the touch surface 205. The preconditioned mode can be entered into automatically as a startup mode when started or be based on whether the seat 200 is occupied (e.g., based on a signal detected by a sensor 280, as shown in FIG. 2A, or received from the vehicle environmental system), whether has been a remote start of the vehicle, or on environmental conditions such as temperatures within the cabin of the vehicle or exterior temperatures or other conditions. The heating or cooling mode can also be entered automatically. An interior or exterior temperature that is higher than the set point temperature of the system 100 (e.g., as received from the vehicle environmental system) can cause the system 100 to enter into a cooling mode. An interior or exterior temperature that is lower than the set point temperature of the system 100 can cause the system 100 to enter into a heating mode.

At Step 325, the system 100 can be set to the low-flow/high delta-T configuration. The low-flow/high delta-T configuration can include a calibrated blower speed and setting the TED power to fully power (e.g., 100%). In this configuration, the system 100 can provide a high delta-T to the touch surface 205. The low-flow/high delta-T configuration can be operated in either the heating or cooling modes. The low-flow/high delta-T configuration can be entered into based on receiving a signal the seat 200 is unoccupied.

At Step 335, the system 100 can remain in the low-flow/high delta-T configuration to precondition the seat 200 with the TED 120 at high (or full) power until the set temperature is reached. The set temperature being reached may be based on a signal from a heat sensor (e.g., NTC) in the system 100, based on a timer, based on a model of the seat 200 and/or cabin conditions. At Step 345, the amount of power provided to the TED 120 can be reduced using a duty cycle through pulse-width modulation (PWM). This can allow maintaining the high delta-T at the seat surface 206 but reduce the overall power that is consumed by the system 100. Generally, the power provided to the TED 120 is the majority of the power used by the system 100. Reducing the power to the TED 120 can be based on achieving the set temperature.

At Step 355, the system 100 can remain in the low-flow/high delta-T configuration based on a preconditioning criteria. If the preconditioning criteria is met, then the system may exit the low-flow/high delta-T configuration. In one option, the system 100 can transition to the nominal-flow configuration described above, or turn off. The response of the system 100 may be based on the preconditioning criteria being met. The preconditioning criteria may include a signal that the seat 200 become occupied, a timer, reaching the set point temperature, comparison with an ambient temperature within the cabin, whether the vehicle is started or shut off, or other criteria. The preconditioning criteria being met at any time during operation of the low-flow/high delta-T configuration and the controller can alter operation of the system 100 accordingly.

At Step 365, the system 100 can increase the speed or volume of the airflow. The system 100 can transition from the low-flow/high delta-T configuration to enter the nominal-flow configuration in either a heating or cooling mode. The flow control valve 140 can be opened to a more neutral position and/or the blower speed of the blower 150 can be increased. In the nominal-flow configuration, the system 100 has the increased ability to change the temperature of the touch surface, particularly if the touch surface 205 is occupied. The system 100 can remain in the nominal-flow configuration until another system criteria is met at Step 375. The transition between the low-flow/high delta-T configuration and the nominal-flow configuration can include movement or movements of the flow control valve 140. This movement can be gradual or sudden. For a gradual movement, the movable flap 144 can pivot a few degrees at a time and be repeated as necessary to complete the transition. For a sudden movement, the movable flap 144 can pivot through large sweeping angles in a short time frame.

At Step 375, an ambient air temperature or set point temperature within the vehicle cabin or ambient environment is reached. Based on this criteria, or another, the system 100 can enter the vent configuration at Step 385. The flow control valve 140 can be moved to block the waste side flow path 134 and/or the blower speed of the blower 150 can be increased. In the vent configuration, the TED can turn off or reduce duty cycle. The blower 150 can blow air from the ambient environment into the passageway 202 to cool the touch surface 205. The system can detect whether the seat 200 remains occupied. The volume of airflow can accordingly be increased to afford adequate ventilation, drying or cooling. In certain implementations, the vent configuration may be used only for cooling the touch surface 205. The transition between the nominal-flow configuration and the vent configuration can include gradual or sudden movement or movements of the flow control valve 140.

### Seat Occupation Determination

In certain implementations, whether the seat 200 is occupied can be based on receiving a signal from a sensor (e.g., force sensor 280 on seat 200) or assumed based on a remote start or other criteria. Another aspect of the present disclosure is determining whether the seat 200 is occupied based on the response of the system 100. According to one implementation, the energy required by the blower 150 can be measured. The data of the blower energy can indicate whether there is blockage of the touch surface, which in turns indicates that the touch surface is occupied. According to another implementations, for a given position of the flow control valve 140, blower 150 speed, and/or TED 120 power, there is an expected delta-T between the temperature of the TED 120 (e.g., main side 122, as measured by NTC 171) and a temperature of ambient cabin air. By comparing this expected delta-T with a measured or calculated delta-T of the ambient cabin air and the temperature of the TED 120, the occupied state of the seat 200 can be determined. If the delta-T is out of the expected range for an occupied or unoccupied seat at current conditions, this information can indicate that the seat is actually unoccupied or occupied. Accordingly, the system 100 itself can be used to determine an occupancy state of the seat 200. According to another technique, determining whether the seat 200 or other surface is occupied is based on a signal received from a vehicle occupant detection system including image/video based systems, driver monitoring system, or occupant monitoring system.

### Certain Terminology

Terms of orientation used herein, such as “top,” “bottom,” “proximal,” “distal,” “longitudinal,” “lateral,” and “end,” are used in the context of the illustrated example. However, the present disclosure should not be limited to the illustrated orientation. Indeed, other orientations are possible and are within the scope of this disclosure. Terms relating to circular shapes as used herein, such as diameter or radius, should be understood not to require perfect circular structures, but rather should be applied to any suitable structure with a cross-sectional region that can be measured from side-to-side. Terms relating to shapes generally, such as “circular,” “cylindrical,” “semi-circular,” or “semi-cylindrical” or any related or similar terms, are not required to conform strictly to the mathematical definitions of circles or cylinders or other structures, but can encompass structures that are reasonably close approximations.

Conditional language, such as “can,” “could,” “might,” or “may,” unless specifically stated otherwise, or otherwise understood within the context as used, is generally intended to convey that certain examples include or do not include, certain features, elements, and/or steps. Thus, such conditional language is not generally intended to imply that features, elements, and/or steps are in any way required for one or more examples.

Conjunctive language, such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain examples require the presence of at least one of X, at least one of Y, and at least one of Z.

The terms “approximately,” “about,” and “substantially” as used herein represent an amount close to the stated amount that still performs a desired function or achieves a desired result. For example, in some examples, as the context may dictate, the terms “approximately,” “about,” and “substantially,” may refer to an amount that is within less than or equal to 10% of the stated amount. The term “generally” as used herein represents a value, amount, or characteristic that predominantly includes or tends toward a particular value, amount, or characteristic. As an example, in certain examples, as the context may dictate, the term “generally parallel” can refer to something that departs from exactly parallel by less than or equal to 20 degrees. All ranges are inclusive of endpoints.

### SUMMARY

Several illustrative examples of climate control systems and control algorithms have been disclosed. Although this disclosure has been described in terms of certain illustrative examples and uses, other examples and other uses, including examples and uses which do not provide all of the features and advantages set forth herein, are also within the scope of this disclosure. Components, elements, features, acts, or steps can be arranged or performed differently than described and components, elements, features, acts, or steps can be combined, merged, added, or left out in various examples. All possible combinations and subcombinations of elements and components described herein are intended to be included in this disclosure. No single feature or group of features is necessary or indispensable.

Certain features that are described in this disclosure in the context of separate implementations can also be implemented in combination in a single implementation. Conversely, various features that are described in the context of a single implementation also can be implemented in multiple implementations separately or in any suitable subcombination. Moreover, although features may be described above as acting in certain combinations, one or more features from a claimed combination can in some cases be excised from the combination, and the combination may be claimed as a subcombination or variation of a subcombination.

Any portion of any of the steps, processes, structures, and/or devices disclosed or illustrated in one example in this disclosure can be combined or used with (or instead of) any other portion of any of the steps, processes, structures, and/or devices disclosed or illustrated in a different example or flowchart. The examples described herein are not intended to be discrete and separate from each other. Combinations, variations, and some implementations of the disclosed features are within the scope of this disclosure.

While operations may be depicted in the drawings or described in the specification in a particular order, such operations need not be performed in the particular order shown or in sequential order, or that all operations be performed, to achieve desirable results. Other operations that are not depicted or described can be incorporated in the example methods and processes. For example, one or more additional operations can be performed before, after, simultaneously, or between any of the described operations. Additionally, the operations may be rearranged or reordered in some implementations. Also, the separation of various components in the implementations described above should not be understood as requiring such separation in all implementations, and it should be understood that the described components and systems can generally be integrated together in a single product or packaged into multiple products. Additionally, some implementations are within the scope of this disclosure.

Further, while illustrative examples have been described, any examples having equivalent elements, modifications, omissions, and/or combinations are also within the scope of this disclosure. Moreover, although certain aspects, advantages, and novel features are described herein, not necessarily all such advantages may be achieved in accordance with any particular example. For example, some examples within the scope of this disclosure achieve one advantage, or a group of advantages, as taught herein without necessarily achieving other advantages taught or suggested herein. Further, some examples may achieve different advantages than those taught or suggested herein.

Some examples have been described in connection with the accompanying drawings. The figures are drawn and/or shown to scale, but such scale should not be limiting, since dimensions and proportions other than what are shown are contemplated and are within the scope of the disclosed invention. Distances, angles, etc. are merely illustrative and do not necessarily bear an exact relationship to actual dimensions and layout of the devices illustrated. Components can be added, removed, and/or rearranged. Further, the disclosure herein of any particular feature, aspect, method, property, characteristic, quality, attribute, element, or the like in connection with various examples can be used in all other examples set forth herein. Additionally, any methods described herein may be practiced using any device suitable for performing the recited steps.

For purposes of summarizing the disclosure, certain aspects, advantages and features of the inventions have been described herein. Not all, or any such advantages are necessarily achieved in accordance with any particular example of the inventions disclosed herein. No aspects of this disclosure are essential or indispensable. In many examples, the devices, systems, and methods may be configured differently than illustrated in the figures or description herein. For example, various functionalities provided by the illustrated modules can be combined, rearranged, added, or deleted. In some implementations, additional or different processors or modules may perform some or all of the functionalities described with reference to the examples described and illustrated in the figures. Many implementation variations are possible. Any of the features, structures, steps, or processes disclosed in this specification can be included in any example.

In summary, various examples of climate control systems and related methods have been disclosed. This disclosure extends beyond the specifically disclosed examples to other alternative examples and/or other uses of the examples, as well as to certain modifications and equivalents thereof. Moreover, this disclosure expressly contemplates that various features and aspects of the disclosed examples can be combined with, or substituted for, one another. Accordingly, the scope of this disclosure should not be limited by the particular disclosed examples described above, but should be determined only by a fair reading of the claims.

1. A control method for conditioning a surface with a thermal conditioning system having a thermoelectric device (TED), comprising:
determining whether the surface is occupied;
providing power to the TED, the TED including a main side and a waste side;
providing an airflow with a blower; and
adjusting a proportion of the airflow between a main side flow path across the main side of the TED and a waste side flow path across the waste side of the TED based on whether the surface is occupied.

2. The control method of claim 1, wherein determining whether the surface is occupied is based on a signal received from a force sensor in a vehicle seat.

3. The control method of claim 1, wherein determining whether the surface is occupied is based on whether a vehicle is remotely started.

4. The control method of claim 1, wherein the control method is a startup mode.

5. The control method of claim 1, wherein determining whether the surface is occupied is based on comparing a delta-T between a temperature of the TED and a temperature of ambient cabin air with an expected delta-T between the temperature of the TED and the temperature of ambient cabin air based at least on a position of a flow control valve.

6. The control method of claim 1, wherein the thermal conditioning system is operated in a heater mode.

7. The control method of claim 1, wherein the thermal conditioning system is operated in a cooling mode.

8. The control method of claim 1, wherein the power provided to the TED is based on whether the surface is occupied.

9. The control method of claim 8, wherein the power provided to the TED is based on the surface being determined to be unoccupied.

10. The control method of claim 9, wherein the power provided to the TED is 100%.

11. The control method of claim 1, wherein adjusting the proportion of the airflow between the main side flow path and the waste side flow path includes adjusting a position of a flow control valve to a first position.

12. The control method of claim 11, wherein the first position of the flow control valve is based on the surface being determined to be unoccupied.

13. The control method of claim 12, wherein the first position of the flow control valve directs the airflow between the main side flow path and the waste side flow path at a ratio between 1:99 and 30:70.

14. The control method of claim 11, further comprising adjusting the flow control valve to a second position based on detecting a set temperature of the airflow.

15. The control method of claim 14, wherein the second position of the flow control valve directs more airflow along the main side flow path than in the first position.

16. The control method of claim 14, wherein the second position of the flow control valve directs the airflow between the main side flow path and the waste side flow path at a ratio between 30:70 and 95:5.

17. The control method of claim 14, further comprising regulating the power provided to the TED based on detecting the set temperature of the airflow.

18. The control method of claim 17, wherein the power provided to the TED is reduced based on detecting the set temperature.

19. The control method of claim 14, further comprising adjusting the flow control valve to a third position based on an in-cabin air temperature.

20. The control method of claim 19, wherein the third position closes the waste side flow path.

21. The control method of claim 19, wherein the in-cabin air temperature is based on a signal from an NTC.

22. The control method of claim 19, wherein the power provided to the TED is reduced based on the in-cabin air temperature.

23. The control method of claim 22, wherein the power provided to the TED is shut off.

24. The control method of claim 14, further comprising increasing a speed of the blower to increase a speed of the airflow.

25. The control method of claim 11, wherein the first position of the flow control valve is based on the surface being determined to be occupied.

26. The control method of claim 25, wherein the first position of the flow control valve directs the airflow between the main side flow path and the waste side flow path at a ratio between 30:70 and 95:5.

27. The control method of claim 11, further comprising adjusting the flow control valve to a second position based on determining that the surface has changed from unoccupied to occupied.

28. The control method of claim 27, wherein the second position of the flow control valve directs more airflow along the main side flow path than in the first position.

29. The control method of claim 27, further comprising adjusting the flow control valve to a third position based on an in-cabin air temperature.

30. The control method of claim 1, wherein determining whether the surface is occupied is based on a signal received from a vehicle occupant detection system.

31.-54. (canceled)
